(19) United States
(12) Patent Application Publication
(10) Pub. No.: US 2009/0194830 A1
(43) Pub. Date: Aug. 6, 2009

(54) SEMICONDUCTOR DEVICE TRANSDUCER AND METHOD

(76) Inventors: James Ransley, Cambridgeshire (GB); Colm Durkan, Cambridge (GB); Ashwin Seshia, Cambridgeshire (GB)

Correspondence Address: NEXSEN PRUET, LLC, P.O. BOX 10648, GREENVILLE, SC, 29603, US

(21) Appl. No.: 12/306,619

(22) PCT Filed: Jun. 27, 2007
(86) PCT No.: PCT/GB2007/002399

§ 371 Date: Feb. 12, 2009

(30) Foreign Application Priority Data
Jun. 27, 2006 (GB) 0612754.2

(51) Int. Cl. H01L 29/84; H01L 21/02; H03K 3/01

(52) U.S. Cl. 257/415; 438/50; 327/534; 257/E29.324; 257/E21.002

(57) ABSTRACT

A semiconductor device such as a resonant device has a capacitive, non-piezoelectric, actuator, the actuator comprising a depletion region. A capacitive actuator for a semiconductor device, a method for fabricating such an actuator, and a method for operating a semiconductor device are also provided. In the operating method, a drive voltage is applied across the depletion region of the semiconductor device, such as a drive voltage having an alternating voltage component for driving a resonant semiconductor device.

The invention relates to a transducer and a method for a semiconductor device, and in particular to a capacitive, or electrostatic, transducer and method for a semiconductor device. One anticipated application of the transducer would be to excite resonant silicon microstructures.

Silicon microresonators can be used in a number of electronic signal processing applications, such as local oscillators and for RF and IF bandpass filtering for wireless communications. This may enable the replacement of existing piezoelectric quartz crystal technology in cell phones allowing for system improvements in cost, size and power dissipation. Additionally silicon microresonators can be configured as sensitive microbalances by detecting the change in the resonant frequency or electromechanical impedance as mass is added to the resonator. Typical applications of existing microbalances include monitoring the thickness of a deposited metal film, or use as a biological sensor by coating the device in a chemical that responds in a specific way to the biological entity to be detected.

Many different silicon resonator structures are described in the prior art, including two-port lateral-bar resonators (of overall shape similar to that illustrated in FIG. 3 below) and more complex resonator structures. A silicon resonator cannot be driven in the same way as a conventional piezoelectric quartz resonator, and the prior art set out below describes a number of drive mechanisms that have been proposed. Examples are described in prior art documents such as;

A 12 MHz micromechanical bulk acoustic mode oscillator” by T. Mattila et al., Sensors and Actuators A101 (2002) pages 1-9, Elsevier;

“Square-extensional Mode Single-Crystal Silicon Micromechanical Resonator for Low-Phase-Noise Oscillator Applications” by V. Kaajakari et al.,

IEEE Electron Device Letters, Vol. 24, No. 4, April 2004, pp 173-75;

“Internal Electrostatic Transduction of Bulk-Mode MEMS Resonators” by S. A. Bhave and R. T. Howe, Solid State Sensor, Actuator and Microsystems Workshop, Hilton Head Island, S. C., Jun. 6-10, 2004.

“Silicon Nitride-on-Silicon Bar Resonator using Internal Electrostatic Transduction” by S. A. Bhave and R. T. Howe, Transducers '05, The 13^{th} International Conference on Solid-State Sensors, Actuators and Microsystems, Seoul, Korea, Jun. 5-9, 2005;

U.S. patent application Ser. No. 11/146,303, publication No. US 2006/0017523 A1, of S. A. Bhave and R. T. Howe.

“Channel-Select Micromechanical Filters using High K Dielectrically Transduced MEMS Resonators” by H Chandrahalim et al, MEMS 2006, As Istanbul, Turkey, 22-26 Jan. 2006 2006, pp 894-897; and

“Dielectrically Transduced Single-Ended to Differential MEMS Filter” by D. Weinstein et al., 2006 IEEE International Solid-State Circuits Conference, pp 318-319.

### STATEMENT OF INVENTION

The invention provides a semiconductor device, a capacitive or electrostatic transducer, a method for fabricating a capacitive or electrostatic transducer and a method for operating a semiconductor device as defined in the appended independent claims, to which reference should now be made. Preferred or advantageous features of the invention are set out in dependent subclaims.

In its various aspects the invention may thus provide;
1. A semiconductor device having a capacitive actuator, the actuator comprising a depletion region;
2. An actuator for a semiconductor device, comprising a depletion region;
3. A method for fabricating a capacitive actuator for a semiconductor device, comprising the steps of doping a first region of the semiconductor device to form a first electrode region of the capacitive transducer and forming a second electrode region of the capacitive transducer such that a depletion region is formable between the electrode regions; and
4. A method for operating a micromechanical semiconductor device, comprising the step of applying a drive voltage across a depletion region of the semiconductor device.

Advantageously, unlike for example prior art quartz devices, a device embodying the invention is substantially capacitively and not piezoelectrically driven (i.e. non-piezoelectric), or is fabricated from substantially non-piezoelectric materials.

The invention may thus advantageously provide-a semiconductor device fabricated primarily or entirely from non-piezoelectric materials (particularly a micromechanical device such as a resonator) in which a capacitive or electrostatic transducer comprises a depletion region or depletion layer (also known as a space-charge region, as described for example in “Semiconductor Devices, Physics and Technology”, by S. M. Sze, published by John Wiley & Sons, Inc). The depletion region may advantageously be part of, or integral with, the semiconductor material of the device.

The transducer may comprise two conductive regions or layers adjacent to the depletion region, between which a voltage may be applied, such that an electric field is applied across the depletion region. The conductive regions may thus effectively provide first and second electrodes, or electrode regions, of the capacitive or electrostatic transducer.

The transducer may be employed as an actuator, for example for a mechanical resonator, as follows. When an electric field is applied across the depletion region, a compressive stress is exerted thereon. This stress results from the force between the uncompensated dopant charges in the depletion region. Since the size of the depletion region varies with the applied voltage, both this force and the compressive stress vary with the applied electric field. When a suitable AC field is applied, for example by applying an AC voltage with a reverse biasing DC offset to the first electrode of the actuator while the second electrode is grounded, the resonator is thus driven. The transducer may also function as a sensor, because the change in the size and hence the charge of the depletion layer results in a current flowing through the device, which can be monitored. For example in the embodiment described above a current may flow to the second, grounded, electrode. This current may therefore be used to sense the movement of the resonator.

In their prior art paper in Transducers '05 referenced above, S. A. Bhave and R. T. Howe describe a two-port lateral-mode bar resonator fabricated from silicon in which a layer of silicon nitride is deposited on an upper surface of the silicon bar, and then a layer of polysilicon is deposited onto the silicon nitride. Deposition is performed in two separate regions of the surface of the silicon bar, to form an electrostatic actuator and a separate sensor. The silicon nitride forms the dielectric, and the polysilicon and the silicon bar form the two electrodes, of each of these transducers. Provided the bonding between the silicon resonator and the SiN dielectric is sufficient, and the mechanical properties of the two materials are adequately matched, strain in the SiN may be transferred to the underlying Si resonator and strain in the resonator may be transferred to the SiN layer. In that case, the SiN dielectric may function as the core of a capacitive transducer, for actuation or sensing. In their 2004 paper and their US patent application referenced above, S. A. Bhave and R. T. Howe describe a similar transduction structure for bulk-mode micromechanical resonators in which electrode gaps are filled with a dielectric material having a much higher permittivity than air. Dielectric materials proposed are titanium dioxide, hafnium oxide, silicon nitride, alumina and silicon dioxide. This transduction structure is also described as being operable such that the dielectric may function as the core of a capacitive transducer, for actuation or sensing.

It can be seen, however, that the transducer embodying the invention provides an improved transducer structure. For example, no deposition of a separate dielectric may be required, and in a preferred embodiment of a resonator, the transducer may be fabricated entirely from the resonator material itself, modified only by a surface implant. This means that the mechanical properties of the resonator may advantageously be substantially unaltered by the presence of the transducer.

It is known in the prior art to fabricate silicon-only resonators, but these use air-gap capacitive transducers, in which an electric field is applied between the silicon resonator and a fixed electrode, separated from the resonator by a narrow air gap. However, embodiments of the invention may provide significant advantages over such structures, for example because the need for fabricating narrow gaps for actuation and sensing may be avoided and because integral or internal capacitive actuation and sensing may be more effective than air-gap systems.

Advantageously, the invention may provide a semiconductor device in which a capacitive transducer comprises a depletion region of the semiconductor from which the device is made. Preferably, one or both of the electrodes (or electrode regions) on either side of the depletion region may also comprise a region or regions of the semiconductor from which the device is made. If only one of the electrodes is formed in this way, then the other electrode may be formed by depositing a layer of material on a surface of the semiconductor. The layer may, for example, be of polysilicon or of metal. In each case, the depletion region may be implemented as a junction, such as a semiconductor/semiconductor junction or a semiconductor/metal junction. For example the junction may be a p-n junction or a metal-semiconductor junction forming a Schottky barrier.

In each case, during operation the junction may advantageously be reverse biased in order to increase the width of the depletion region as well as to increase the voltage that may be applied across it for use as a transducer.

Thus, in one embodiment one electrode may comprise an ion-implanted or dopant-diffused layer at or beneath the surface of a semiconductor and the other electrode may comprise the semiconductor adjacent to the implanted layer; the depletion region forms around the junction (optionally reverse biased) between the electrodes. In a second embodiment, the electrodes may respectively comprise the semiconductor itself and a layer applied to the surface of the semiconductor, such as a polysilicon layer. In a third embodiment, the electrodes may respectively comprise the semiconductor itself and a surface layer of metal, applied to the semiconductor surface. In the second and third embodiments, the depletion region may then form at a junction between the semiconductor and the surface layer.

In each embodiment, suitable doping of the electrodes and/or the dielectric region and/or surface layer may be implemented as required, for example in order to achieve appropriate conductivity of the electrodes and appropriate properties of the depletion region at the junction.

In a further embodiment, the capacitive transducer may comprise more than two electrodes. For example, a stack of three or more electrodes may be formed, with junctions (and therefore depletion regions) between each adjacent pair of electrodes. In an example of such a structure, the semiconductor material of the device may be n-doped and a stack of spaced p-type layers may be implanted by ion implantation, using different implantation energies and/or doses and/or ion species. Depletion regions may then form at each junction in the stack between an n-type and a p-type region.

In such an embodiment, it may be desired to connect alternate electrodes in the stack together so that, for example, a drive voltage may be applied to a set of alternate electrodes or a set of alternate electrodes may be grounded. Thus, in a stack in which the electrode regions comprise alternate n-type and p-type regions, the n-type regions may be connected together and/or the p-type regions may be connected together. Each such connection may be fabricated, for example, using a separate ion implant through a further mask, to form an electrical contact for the transducer.

In a preferred embodiment, the transducer, or actuator, comprises a p-n junction or a metal-semiconductor junction. The p-n junction may be produced by a p-type implant (such as a surface implant) into an n-type wafer (from which the semiconductor device may be formed). Other topologies may be used, including stacks of p-n junctions or deep implants and diffusions in which the active surface of a p region (at which a depletion region forms) lies in a plane perpendicular to that of the semiconductor device, or resonator.

The bulk of the wafer is preferably grounded, or earthed, and a bias signal applied to the implant, or each of the implants in a stack, or the metal or other surface layer. Actuation of the resonator may be obtained by applying a reverse bias, to increase the width of the depletion region, and superimposing an AC carrier of a predetermined frequency on the DC voltage. The AC voltage excites a time-varying electric field across the depletion region or regions of the transducer. This in turn produces a force between the positively and negatively charged regions of the depletion region of the junction, which acts in a direction to compress the semiconductor in the depletion region. Depending on the geometry of the semiconductor device, this can be used to drive modes which oscillate in, for example, the direction perpendicular to the depletion region or in the plane parallel to it, as the Poisson's ratio of the semiconductor (e.g. silicon) leads to a deformation in this plane when the transducer is actuated. The latter type of mode includes thickness shear modes and bulk acoustic modes, which typically have very large mechanical Quality factors and may be particularly suitable for resonant device applications.

In embodiments using semiconductor-semiconductor junctions, such as p-n junctions, to provide depletion regions, junctions may conveniently be formed by creating p-doped regions within an n-doped semiconductor, or n-doped regions within a p-doped semiconductor. The doping may be performed in any convenient manner, including by way of example ion implantation or diffusion techniques. As the skilled person would appreciate, embodiments of the invention comprising semiconductor junctions may be of similar general structure to varactors, or variable reactors. In embodiments in which metal-semiconductor junctions are used, junctions may be formed between the semiconductor and any metal with a suitable work function, to create a depletion region. For silicon devices, such metals include platinum and tungsten.

Other structures such as MOS diode structures under inversion and/or depletion may also be used in embodiments of the invention.

Advantageously, the semiconductor is silicon. Silicon has mechanical properties that are very suitable for resonant devices. In addition, silicon devices may be fabricated using existing semiconductor manufacturing technologies. Integrated circuits, for example CMOS circuits, can also be fabricated on silicon. CMOS technology may be used to perform some of the steps required to fabricate devices embodying the invention, such as the formation of doped layers or metal surface layers, as required. It is also straightforward to use existing semiconductor manufacturing technology to array a large number of devices on a substrate of small size, which may enable a plurality of devices embodying the invention to be fabricated on a single chip. A further advantage of using a silicon-based technology is the possibility of integrating signal processing and conditioning electronics on the same chip so that a single chip may provide, for example, a complete signal-processing system or biological measurement system, considerably reducing the cost of a system. Such an integrated system may also advantageously be smaller in size than a prior art system using quartz resonators separate from a chip carrying the associated circuitry.

In addition, the prior art contains descriptions of the fabrication of a wide range of resonant devices from silicon wafers, such as silicon-on-insulator (SOI) wafers. The additional steps required to implement the capacitive transducer of the invention are straightforward and could easily be incorporated by the skilled person into existing fabrication processes. Such processes in silicon and other semiconductor fabrication routes are fairly standard micromachining processes and advantageously amenable to low-cost high-volume production. For example, resonant devices may be fabricated from existing CMOS processed SOI wafers with a single stage of photolithography followed by a deep reactive-ion etch and removal of the box oxide by an isotropic etch (in this case any implanted regions and metallisation required are assumed to be provided by the CMOS process).

Although silicon is a particularly advantageous material in these respects, other semiconductors may also be used to implement the invention, particularly where conventional fabrication technologies can be used.

In a further aspect, a depletion layer in a resonant device embodying the invention may be reverse-biased with a predetermined bias voltage in order to apply a stress to the resonant device so as to shift the resonant frequency of the device. Variation of the bias voltage may thus vary and control the resonant frequency. This may be used in a feedback loop, for example, in order to fix the frequency of oscillation of the device as the device temperature varies. (The oscillation frequency may otherwise vary with temperature, as in conventional resonant devices.)

The skilled person would be aware of a wide range of applications for embodiments of the invention including, but not limited to, resonant microbalances, timing references and filters, and including free-standing structures, non-free-standing structures, horizontal structures and vertical structures.

### DESCRIPTION OF SPECIFIC EMBODIMENTS AND BEST MODE OF THE INVENTION

Specific embodiments of the invention will now be described by way of example, with reference to the accompanying drawings, in which:

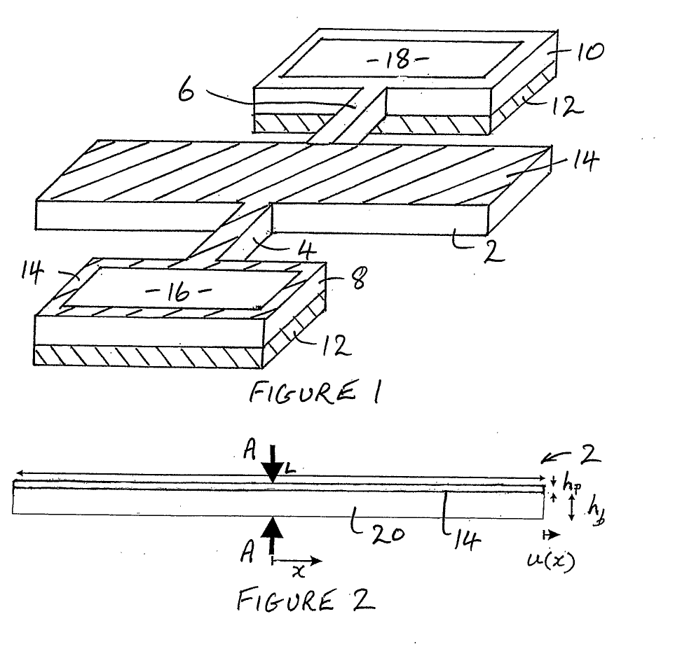

FIG. 1 is a three-quarter view of a one-port silicon lateral bar resonator incorporating a capacitive transducer according to a first embodiment of the invention;

FIG. 2 is a schematic, longitudinal section of the bar of the resonator of FIG. 1;

FIG. 3 is a three-quarter view of a resonator according to a further embodiment, comprising an actuator and a separate sensor;

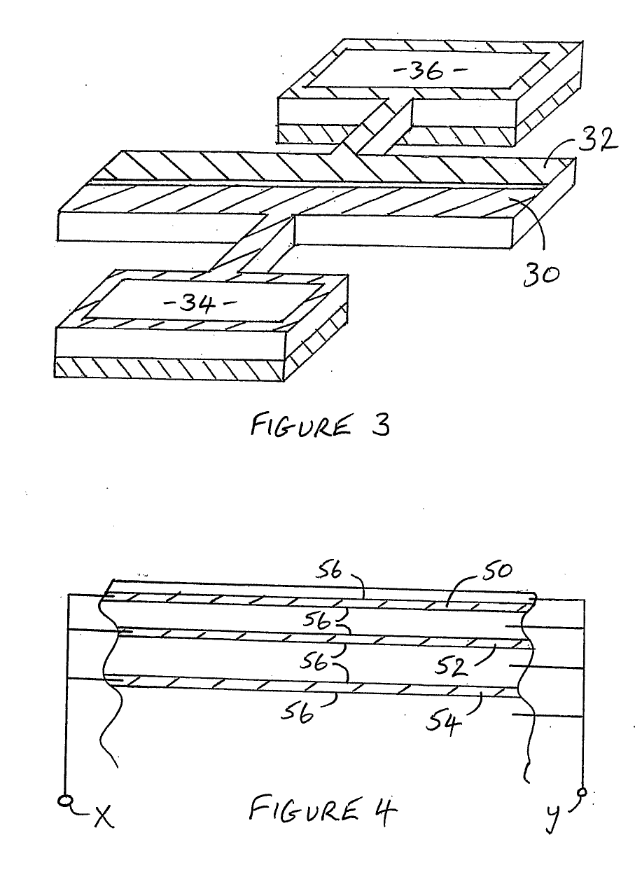

FIG. 4 is a schematic cross-section of a capacitive transducer comprising a plurality of junctions, according to a further embodiment of the invention;

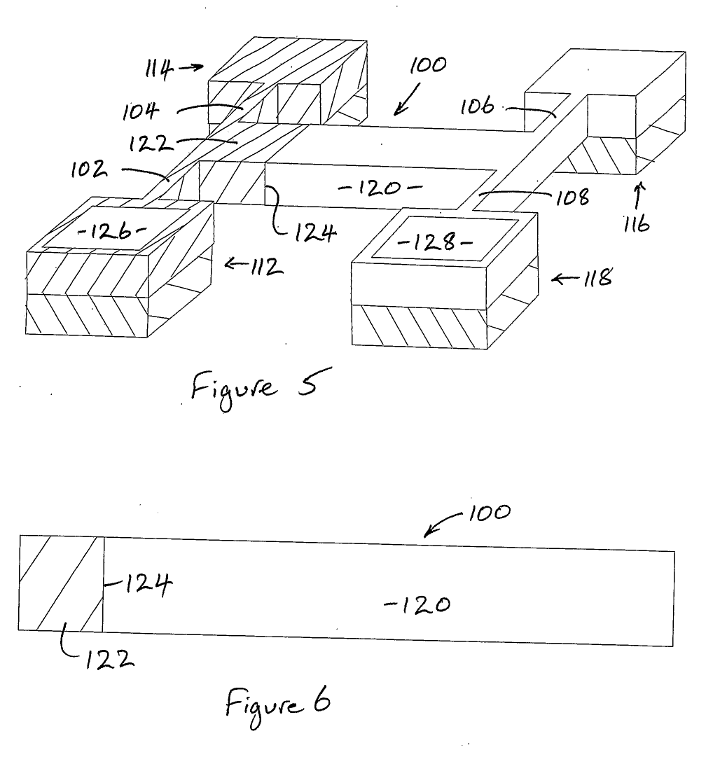

FIGS. 5 and 6 are a three-quarter view and a longitudinal section of a further embodiment of the invention, in the form of a vertical-structure resonator; and

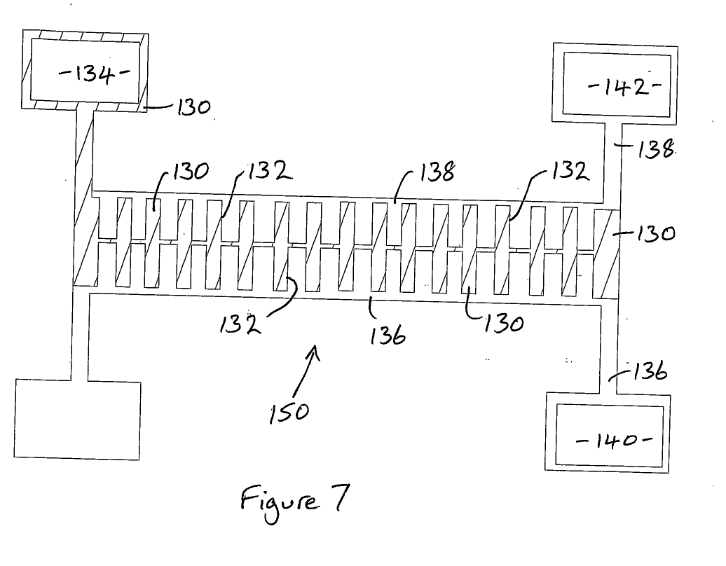

FIG. 7 is a plan view of a further embodiment, comprising a shaped p-type region; and

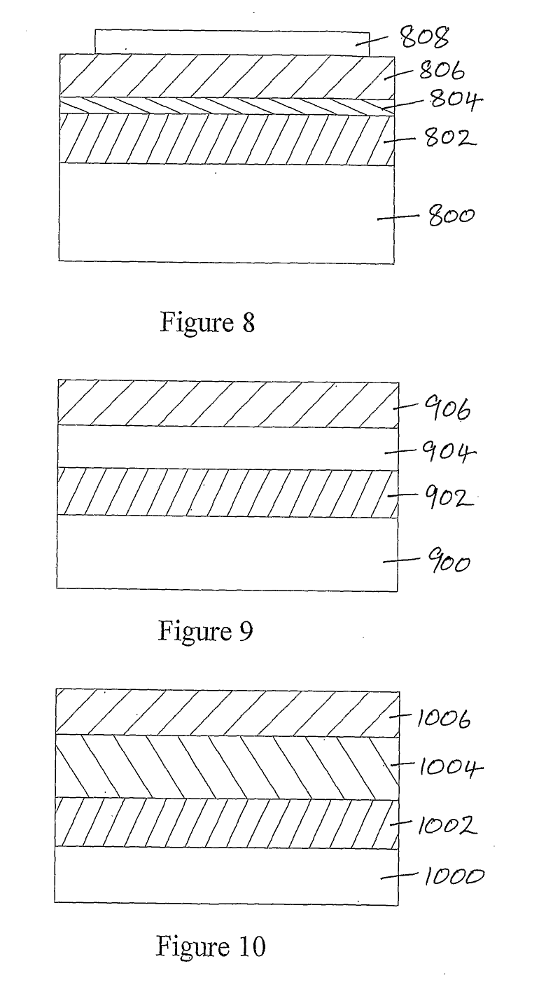

FIGS. 8 to 10 illustrate cross-sections of further semiconductor structures for use in embodiments of the invention.

The embodiment of FIG. 1 comprises a one-port silicon lateral bar resonator fabricated from a silicon-on-insulator (SOI) wafer. The resonator bar 2 is a free-standing structure supported at its midpoint by two silicon bridges (or suspension elements) 4, 6 leading to respective supports 8, 10 on each side of the bar. The supports stand on the underlying oxide 12, which is in turn connected to the handle, or remaining structure of the SOI wafer, which is omitted from FIG. 1 for clarity.

The resonator device of FIG. 1 is fabricated as follows, in a generally similar manner to the devices described in the prior art referenced above, for example by Mattila et al and by Bhave and Howe, but using a different step to form the capacitive transducer. The fabrication starts with a SOI wafer, with a 3 μm thick n-type device layer, doped (e.g. by As, P) to a concentration of 2×10¹⁷ cm⁻³. It is possible to use a wafer that has been pre-processed by a foundry (e.g. a CMOS processed wafer) for this process and in the embodiment we assume that we are. Pre-processed wafers are in general covered with a thick passivation oxide, which can be used as a mask for implants (ion implantation). Assuming that this is the case, fabrication starts by defining, by lithography, a region in which the resonator bar, the bridges and the supports are to be formed. The passivation oxide is then thinned in this region down to a thickness of a few nm (e.g. 50 nm) with a timed etch in buffered HF, so that we can implant through it. A region for ion implantation is then defined by a second step of lithography, the region corresponding to the upper surface of the resonator bar 2, one of the bridges 4, and the adjacent support 8. A p-type region (e.g. doped with B) is then produced on this region of the surface of the resonator by a low-energy ion implant. In the embodiment, the implant dose is chosen such that the dopant concentration of the implant is several orders of magnitude greater than that of the silicon device layer beneath the implant (e.g. 10¹⁹ cm⁻¹³) to produce an abrupt, one-sided junction between the p-type and n-type regions. Following a further step of lithography, holes are then etched through the passivation oxide (again with buffered HF) in regions above the two supports 8, 10, and aluminium contacts 16, 18 are evaporated onto the upper surfaces of the supports. The metal may be deposited by lift-off without requiring a fourth lithography mask. Thus, one of the aluminium contacts 16 is connected to the implanted p-type region and the other contact 18 is connected to the underlying n-type silicon device layer.

In an alternative embodiment, the structure (including the contacts) could be fabricated using steps that occur in the CMOS process, which would typically include a shallow implant, and contacts to the implant and the underlying Si device layer. In either embodiment, it should be noted that if the device is to be integrated with other electronics fabricated on the same silicon wafer, the interconnects to the rest of the circuit may not need to be metal, in which case the metal deposition step may be omitted.

In either embodiment, a single step of lithography and a deep reactive-ion etch can then be used to define the resonator structure, including the anchored supports 10, 8, by etching through the thickness of the device layer. The resonator itself is then released from the underlying substrate by an HF vapour etch, which removes the oxide from underneath the resonator bar and the bridges. The etch is timed so that the relatively thin resonator bar and the bridges are completely undercut but the thicker supports 8, 10 are not undercut, leaving an oxide layer attaching the supports to the handle. An alternative to using HF vapour is to use a wet etch and employ a sublimation drying technique, as described by Mattila et al above.

FIG. 2 illustrates the resonator bar 2 in longitudinal section, showing the n-type silicon substrate 20 and the ion-implanted p-type layer 14. In FIG. 2, the thickness of the ion-implanted layer is exaggerated for clarity. In addition, the location of the bridges at the midpoint of the bar is indicated by the arrows (A) and the dimensions of the bar are shown for reference in the calculations set out below.

In the description of the first embodiment above, the ion implantation dose is chosen to approximate an abrupt, one-sided junction. This structure may then be modelled using an abrupt junction model, for example as described in Sze (Semiconductor Devices Physics and Technology 2^{nd} Ed, Wiley 2002, page 93). However, capacitive transducers embodying the present invention may use substantially any form of p-n junction and are not limited to abrupt junctions.

The drive mechanism of the capacitive transducer is as follows. Application of a drive voltage to the electrical contacts 16, 18 produces a voltage between the ion-implanted p-type region 14 and the underlying n-type silicon 20, across the depletion region of the p-n junction between them. Preferably, a DC voltage component is applied to reverse bias the junction and increase the size of the depletion region. An AC voltage component is additionally applied at a predetermined frequency to drive the resonator. The p-type and n-type regions act as two electrodes to apply an electric field across the depletion region. The electric field produces a compressive stress between the electrodes. This stress is perpendicular to the plane of the resonator bar but is translated into a stress in the plane of the bar by the Poisson contraction in the material of the depletion region. The variation in the stress in the plane of the bar can be used in this device to drive a bulk acoustic mode, along the length of the bar, with a wavelength λ=2 L (L being the length of the bar). The frequency of the AC voltage should be selected accordingly.

FIG. 3 illustrates a third embodiment of the invention, in which two separate capacitive transducers are formed on the upper surface of the resonator bar, one acting as an actuator 30 and the second as a sensor 32. Electrical contacts 34, 36 are formed on the supports of the resonator and connected to the p-type regions of the actuator and sensor respectively. The underlying n-type silicon is common to both the sensor and the actuator and is electrically connected separately (not shown). The actuator is driven as described above.

A DC voltage is applied to the sensor and varying stresses in the depletion layer of the sensor, and associated varying strains changing the thickness of the depletion region, provide a varying AC current that can be monitored in order to sense vibration of the resonator.

FIG. 4 illustrates a fourth embodiment of the invention. In this embodiment, three p-type layers 50, 52, 54 are formed at different depths beneath the surface of an n-type silicon resonator, producing 6 large area p-n interfaces which all act as described above. In similar embodiments, two or more layers may be implanted. The layers at different depths can be formed by ion implantation at different energies and doses, for example. One of the p-type layers may be at the surface of the n-type silicon resonator, although in the embodiment illustrated in FIG. 4 all of the p-type layers are implanted beneath the surface. In this embodiment, as schematically illustrated in FIG. 4, the p-type regions may be connected to a first electrical contact X and the n-type regions between the p-type layers connected to a second electrical contact Y. Depletion layers 56 will form at each junction between p-type and n-type, that is on either side of each p-type region. The application of a DC voltage between the first and second electrical contacts may thus reverse bias all of the junctions and the application of an AC voltage across the first and second contacts may cause compressive stress in each of the depletion regions. This may advantageously increase the compressive stress, and the associated strain, in the capacitive transducer, by comparison with applying a voltage across a single depletion region.

Each of the embodiments above has been described in terms of the formation of p-type regions in an n-type semiconductor structure. As the skilled person would readily appreciate, other doping arrangements may be used, including the formation of n-type regions in a p-type semiconductor structure.

In a fifth embodiment, a resonator structure is fabricated as illustrated in FIG. 1, but instead of forming a p-type layer at or near the surface of the resonator bar, the silicon oxide is completely stripped from the upper surfaces of the bar, one of the bridges and the corresponding support, and a metal layer deposited onto the surface of the silicon in these areas. Deposition of a metal having a suitable work function, such as platinum, produces a depletion region in the silicon adjacent the metal layer. A voltage can then be applied between the metal and the bulk silicon, in the same way as described in the first embodiment, to drive the capacitive transducer and the resonator.

Two metal regions may be deposited in the same way as described in FIG. 3, to form an actuator and a separate sensor.

As the skilled person would appreciate, the silicon beneath the metal layer may be n-type or p-type, as required.

All of the foregoing embodiments are fabricated using silicon. Similar embodiments may be constructed using any suitable semiconductor.

In the foregoing embodiments, the use of transducers as actuators and sensors is described. In a preferred embodiment a transducer may fulfil both functions. For example, a first transducer electrode can be coupled to a DC+AC signal as desired for driving a resonator, while a second electrode is grounded. In that case, in order to keep the second electrode grounded a current must flow between ground and the second electrode because the depletion region changes in size as the voltage across it changes and as the motion of the semiconductor device strains the depletion region. This current may be monitored and used to sense motion of the device, for example by grounding the second electrode through a trans-impedance amplifier.

All of the foregoing embodiments comprise capacitive transducers applied at or beneath the surface of a bar resonator. As the skilled person would appreciate, similar transducer structures may be applied to substantially any form of semiconductor resonator. In addition, the transducer structure itself need not be planar, but could be any suitable shape depending on the structure and excitation mode of the resonator to which it is to be applied.

Each of the embodiments described comprises only a resonator. In each case, however, since the resonator is fabricated from a silicon wafer, other circuitry could be implemented on the same semiconductor device and connected to the resonator appropriately.

Each of the resonators described in the embodiment are free-standing silicon structures driven in a longitudinal mode. Embodiments of the invention may, however, be used to drive non-free-standing resonant structures and to drive resonant structures in any suitable mode.

Further embodiments, shown in FIGS. 5 to 7, illustrate embodiments of the invention in a vertical structure. These embodiments implement transducers for resonators in which the force across the p-n junction(s) of the transducer is parallel to the direction of the motion of the resonator structure.

FIG. 5 illustrates a resonator bar 100 supported at its ends by four bridges 102. 104, 106, 108. Each bridge extends from a support 112, 114, 116, 118 in the same way as in earlier embodiments. This device is fabricated from n-type silicon 120 using similar techniques as in the earlier embodiments, except that the p-type region 122 extends through the entire thickness of the resonator, such that the p-n junction 124 extends through the resonator thickness. FIG. 6 is a longitudinal cross section of the resonator bar, showing that the p-n junction extends through the resonator thickness. Metallised layers 126, 128 provide contacts for the p-type and n-type regions respectively.

By comparison with the earlier embodiments, in this case the implant or diffusion to produce the p-type region needs to be modified to dope to a greater depth. The doping could be performed by a surface diffusion process (provided the device layer is relatively thin, e.g. 1 μm) or by a series of implants of different ion energies and doses. Both processes would need to be tailored to p-dope the device layer through a substantial fraction of the thickness of the device layer. In this case in FIG. 5 we have shown the case where the whole thickness is p-doped (again this would require a sufficiently thin device layer).

FIG. 7 shows in plan view a similar device 150 in which the shape of the p-type region 130 has been modified to increase the surface area of the p-n junction 132 perpendicular to the length of the resonator. As in FIGS. 5 and 6, the p-n junction extends through the thickness of the resonator. The p-type region is connected to a metallised contact 134. The n-type region is in two parts 136, 138 on either side of the p-type region. Each part is connected to a respective metallised contact 140, 142, and the contacts are connected together in use of the transducer.

FIGS. 8 to 10 illustrate cross-sections of further structures which may be used in embodiments of the invention. FIG. 8 shows a depletion layer actuator combined with an FET gate structure biased so that the semiconductor is inverted. This structure comprises the following layers over a Si resonator 800; a depletion region 802, an inversion layer 804, a gate oxide 806 and a metal layer 808, to serve as an electrode. FIG. 9 shows a depletion layer actuator comprising a PIN junction with a narrow insulating region, implanted in undoped Si. This structure comprises the following layers over an undoped resonator 900; an N-type implant 902, an undoped insulating Si layer 904, and a P-type implant layer 906. FIG. 10 shows a depletion layer actuator comprising a PIN junction in which an insulating region is produced by a room-temperature implant of, for example, Si without any subsequent anneal. This structure comprises the following layers formed over a Si resonator 1000; an N-type implant 1002, a disordered implanted Si layer 1004 (retained during fabrication by only carrying out room-temperature processing after this layer is formed) and a metal layer 1006. Fabrication and operation of these structures to implement the invention will be clear to the skilled person in view of his common general knowledge and the description in this patent application.

### Modelling Performance of Capacitive Transducer

The following description models the performance of the embodiment of the invention illustrated in FIGS. 1 and 2, and demonstrates the effectiveness of the capacitive transducer described. The function notation is that of the symbolic mathematics package ‘Mathematica’.

The force between the two plates of the capacitor formed from the depletion region of the pn junction produces a stress in the vertical direction which is translated into a stress in the horizontal direction by the Poisson contraction. In this particular case the device is driven in a bulk acoustic mode, with a wavelength λ=2 L.

The displacement function, u(x), for the resonator in the direction indicated is given by the following function:

$$u [ x ] := a [ t ] \times Sin [ \frac{π \times x}{L} ]$$

Where a[t] is the maximum deflection, at the end of the cantilever. The strain in the silicon in the x direction is therefore given by:

$${ɛ}_{xx} = D [ u [ x ] , x ]$$

$$\frac{π a [ t ] Cos [ \frac{π x}{L} ]}{L}$$

The strain in the junction region in the y and z directions is therefore given by:

ε_{yy}=−νₚₐᵣₐ×ε_{xx;}

ε_{zz}=−νₚₑᵣₚ×εₓₓ;

The elastic potential energy stored in the beam at maximum displacement is given by:

$${W}_{E} = \frac{1}{2} Y \times h \times w \times {\int }_{- L / 2}^{L / 2} {ɛ}_{xx}^{2} d x$$

$$\frac{h {π}^{2} {wYa [ t ]}^{2}}{4 L}$$

(neglecting the energy stored in the dielectric & top electrode, in the case of the capacitive actuation, Y is the youngs modulus of the beam).

The kinetic energy stored in the beam is given by:

$$T = \frac{1}{2} ρ \times h \times w \times {\int }_{- L / 2}^{L / 2} {D [ u [ x ] , t ] }^{2} d x$$

$$\frac{1}{4 } hLw ρ {{a}^{′} [ t ]}^{2}$$

$$\frac{1}{4} hLw ρ {{a}^{′} [ t ]}^{2}$$

This constriction across the p-n junction results from the attractive force between the donors and the acceptors in the depletion region. We assume an abrupt junction with N_{d} [symbol] Nₐ. For a detailed discussion of the physics of this device see S. M. Sze, Semi-conductor Devices. Given this assumption The electric field in the junction is determined by considering the guassian cylinder (area A) that has one end in the n-type region (which has a negligible depletion width compared to the p-type region) and the other a distance a into the p-type depletion region. If w_{dep} is the width of the depletion region the electric field E′ is given by:

$${E}_{f} = \frac{{q}_{electron} \times ( {N}_{d} \times α - {N}_{d} \times wdep )}{ε} ;$$

$$Simplify [ {E}_{f} ] - \frac{( wdep - α ) {N}_{d} {q}_{electron}}{ε}$$

The force on the element of charge density qN_{d}δα at the end of the cylinder is:

$$δ F = {E}_{f} \times {q}_{electron} \times {N}_{d} \times A \times δα$$

$$\frac{A δ α {N}_{d} ( - {wdepN}_{d} + α {N}_{d} ) {q}_{electron}^{2}}{ε}$$

The distance moved by this force at a position x along the beam is:

$$δ z [ x ] = {ɛ}_{zz} \times α - \frac{πα a [ t ] Cos [ \frac{π x}{L} ] {ν}_{perp}}{L}$$

Consider the element located between x and x+δx along the resonator. The work done by this force at this point along the beam is:

$$A = δ x \times w \times q ;$$

$$δ {W}_{pn} = δ F \times δ z [ x ] - \frac{1}{L ε} ( π qw α δ x δα a [ t ] Cos [ \frac{π x}{L} ] {N}_{d} ( \begin{matrix}- {wdepN}_{d} + \\ α {N}_{d}\end{matrix} ) {q}_{electron}^{2} {ν}_{perp} )$$

(note that the factor q introduced in this equation can be taken as 1—it was introduced to allow for devices where there are drive and sense pads in which the drive pad only occupies a faction of the width of the device i.e. w×q)

Therefore the total work done is given by:

$${W}_{pn} = {\int }_{- L / 2}^{L / 2} {\int }_{0}^{wdep} \frac{δ {W}_{pn}}{δ x δα} d α d x$$

$$\frac{{qwwdep}^{3} a [ t ] {N}_{d}^{2} {q}_{electron}^{2} {ν}_{perp}}{3 ε}$$

The depletion width is dependant on the voltage applied to the junction through the following equation:

$$wdep = \sqrt{\frac{2 \times ε \times ( Vpndc + Vpnac )}{{q}_{electron} \times {N}_{d}}}$$

$$\sqrt{2} \sqrt{\frac{( Vpnac + Vpndc ) ε}{{N}_{d} {q}_{electron}}}$$

where V_{pndc} is the (negative) DC offset plus the built in voltage (the total voltage dropped across the reverse biased junction) and V_{pnac} is the AC voltage.

This leaves us with the following expression for wₚₙ:

$${W}_{pn} \frac{2 \sqrt{2} qwa [ t ] {{N}_{d}^{2} ( \frac{( Vpnac + Vpndc ) ε}{{N}_{d} {q}_{electron}} )}^{3 / 2} {q}_{electron}^{2} {ν}_{perp}}{3 ε}$$

The Lagrangian is given by:

$$Lag = T + {W}_{pn } - {W}_{E} - \frac{h {π}^{2 } {wYa [ t ]}^{2}}{4 L} + \frac{2 \sqrt{2} qwa [ t ] {{N}_{d}^{2} ( \frac{( Vpnac + Vpndc ) ε}{{N}_{d} {q}_{electron}} )}^{3 / 2} {q}_{electron}^{2} {ν}_{perp}}{3 ε} + \frac{1}{4} hLw ρ {{a}^{′ } [ t ]}^{2}$$

We know that

$$\frac{d}{d t} ( \frac{\partial Lag}{\partial {a}^{′}} ) - \frac{\partial Lag}{\partial a} = 0.$$

### Therefore:

$$D [ D [ Lag , {a}^{′} [ t ] , ] , t ] - D [ Lag , a [ t ] ] = 0$$

$$\frac{h {π}^{2} wYa [ t ]}{2 L} - \frac{2 \sqrt{2} {{qwN}_{d}^{2} ( \frac{( Vpnac + Vpndc ) ∈}{{N}_{d} {q}_{electron}} )}^{3 / 2} {q}_{electron}^{2} {ν}_{perp}}{3 ∈} + \frac{1}{2} hLw ρ {a}^{″} [ t ] = 0$$

This equation can be identified as a forced simple harmonic oscillator equation of motion. Without a forcing term the following equation is obtained:

$$Solve [ \% /. Vpndc + Vpnac \to 0 , {a}^{\text{``}} [ t ] ]$$

$$\{ \{ {a}^{′′} [ t ] \to - \frac{{π}^{2} Ya [ t ]}{{L}^{2} ρ} \} \}$$

This is a simple harmonic oscillator with resonant frequency

$${ω}_{0}^{2} = \frac{{π}^{2} Y}{{L}^{2} ρ} . \qquad$$

We now make a number of assumptions. First we assume that V[t] [symbol] V_{DC}. Then we change variables from a[t] to b[t], such that b[0]=0.

$$\frac{h {π}^{2} wYa [ t ]}{2 L} - \frac{2 \sqrt{2} {{qwN}_{d}^{2} ( \frac{{V}_{pndc ∈}}{{N}_{d} {q}_{electron}} )}^{3 / 2} ( 1 + \frac{3 Vpnac}{2 Vpndc} ) {q}_{electron}^{2} {ν}_{perp}}{3 ∈} + \frac{1}{2} hLw ρ {a}^{″} [ t ] = 0$$

$$Solve [ \% , a [ t ] ] / \cdot {a}^{″} [ t ] \to 0 / \cdot {V}_{pnac} \to 0$$

$$FullSimplify [ \%\% ] / \cdot \{ a [ t ] \to b [ t ] + \frac{4 \sqrt{2} LqVpndc {N}_{d} \sqrt{\frac{Vpndc ∈}{{N}_{d} {q}_{electron}}} {q}_{electron} {ν}_{perp}}{3 h {π}^{2} Y} , {a}^{″} [ t ] \to {b}^{″} [ t ] \} ;$$

$$Simplify [ \% ]$$

$$\frac{h {π}^{2} wYa [ t ]}{2 L} - \frac{2 \sqrt{2} q ( 1 + \frac{3 Vpnac}{2 Vpndc} ) {{wN}_{d}^{2} ( \frac{Vpndc ∈}{{N}_{d} {q}_{electron}} )}^{3 / 2} {q}_{electron}^{2} {ν}_{perp}}{3 ∈} + \frac{1}{2} hLw ρ {a}^{″} [ t ] = 0$$

$$\{ \{ a [ t ] \to \frac{4 \sqrt{2} LqVpndc {N}_{d} \sqrt{\frac{Vpndc ∈}{{N}_{d} {q}_{electron}}} {q}_{electron} {ν}_{perp}}{3 h {π}^{2} Y} \} \}$$

$$\frac{w ( h {π}^{2} Yb [ t ] + L ( - \frac{2 \sqrt{2} q Vpnac Vpndc ∈ {ν}_{perp}}{\sqrt{\frac{Vpndc ∈}{{N}_{d} {q}_{electron}}}} + hL ρ {b}^{″} [ t ] ) )}{L} = 0$$

$$\frac{h {π}^{2} Yb [ t ]}{h {L}^{2} ρ} - \frac{2 \sqrt{2} q VpnacVpndc ∈ {ν}_{perp}}{hL ρ \sqrt{\frac{Vpndc ∈}{{N}_{d} {q}_{electron}}}} + {b}^{″} [ t ] = 0$$

$$\frac{ {π}^{2} Yb [ t ]}{{L}^{2} ρ} - \frac{2 \sqrt{2} q VpnacVpndc ∈ {ν}_{perp}}{hL ρ \sqrt{\frac{Vpndc ∈}{{N}_{d} {q}_{electron}}}} + {b}^{″} [ t ] = 0$$

Rearranging the above equation into the standard form for a simple harmonic oscillator gives:

$$ω {0}^{2} b [ t ] + {b}^{″} [ t ] = \frac{2 \sqrt{2} q Vpnac {v}_{perp}}{hL ρ} \sqrt{Vpndc ∈ {q}_{electron} {N}_{d}}$$

$$ω {0}^{2} b [ t ] + {b}^{″} [ t ] = \frac{2 \sqrt{2} q Vpnac \sqrt{Vpndc ∈ {N}_{d} {q}_{electron}} {ν}_{perp}}{hL ρ}$$

We can now add a damping term to this equation:

$${b}^{″} [ t ] + \frac{ω 0}{Q} {b}^{′} [ t ] + ω {0}^{2} b [ t ] = \frac{2 \sqrt{2} q Vpnac {v}_{prep}}{hL ρ} \sqrt{Vpndc ∈ {q}_{electron} {N}_{d}}$$

$$ω {0}^{2} b [ t ] + \frac{ω 0 {b}^{′} [ t ]}{Q} + {b}^{″} [ t ] = \frac{2 \sqrt{2} q Vpnac \sqrt{Vpndc ∈ {N}_{d} {q}_{electron}} {ν}_{perp}}{hL ρ}$$

Finally, we assume that V[t]=V₀e^{iωt}, and that a[t] a₀e^{iωt} (note that V₀ and b₀ are potentially complex).

$$Evaluate [ \% / \cdot \{ b [ t ] \to {b}_{0} ⋆ Exp [ i ⋆ ω ⋆ t ] , {b}^{′} [ t ] \to D [ {b}_{0} ⋆ Exp [ i ⋆ ω ⋆ t ] , t ] , {b}^{″} [ t ] \to D [ {b}_{0} ⋆ Exp [ i ⋆ ω ⋆ t ] , \{ t , 2 \} ] , Vpnac \to {V}_{0} ⋆ Exp [ i ⋆ ω ⋆ t ] \} ] \\ - {e}^{i t ω} {ω}^{2} {b}_{0} + \frac{i {e}^{i t ω} ωω 0 {b}_{0}}{Q} + {e}^{i t ω} ω {0}^{2} {b}_{0} = \frac{2 \sqrt{2} {e}^{i t ω} q \sqrt{Vpndc ∈ {N}_{d} {q}_{electron}} {V}_{0} {ν}_{perp}}{hL ρ}$$

This gives us the following equation:

$$Solve [ \% , {b}_{0} ]$$

$$\{ \{ {b}_{0} \to - \frac{2 \sqrt{2} qQ \sqrt{Vpndc ∈ {N}_{d} {q}_{electron}} {V}_{0} {ν}_{perp}}{hL ρ ( Q {ω}^{2} - iωω0 - Q {ω0}^{2} )} \} \}$$

At resonance ω=ω₀ and we have the following expression for b₀:

$$FullSimplify [ \% / \cdot \{ ω \to ω 0 \} ]$$

$$\{ \{ {b}_{0} \to - \frac{2 i \sqrt{2} qQ \sqrt{Vpndc ∈ {N}_{d} {q}_{electron}} {V}_{0} {ν}_{perp}}{hL {ρω0}^{2}} \} \}$$

Finally substituting for ω₀ we obtain:

$$\% / \cdot \{ ω 0 \to Sqrt [ \frac{{π}^{2} Y}{{L}^{2} ρ} ] \}$$

$$\{ \{ {b}_{0} \to - \frac{2 i \sqrt{2} LqQ \sqrt{Vpndc ∈ {N}_{d} {q}_{electron}} {V}_{0} {ν}_{perp}}{h {π}^{2} Y} \} \}$$

So the value of b₀ at resonance is given by:

$$apnres = \frac{2 \sqrt{2} LqQ \sqrt{Vpndc ∈ {N}_{d} {q}_{electron}} {V}_{0} {ν}_{perp}}{h {π}^{2} Y} \frac{2 \sqrt{2} LqQ \sqrt{Vpndc ∈ {N}_{d} {q}_{electron}} {V}_{0} {ν}_{perp}}{h {π}^{2} Y}$$

The stress in the beam takes the following form at the time of the maximum displacement and at resonance:

$${σ}_{pnxx} = Y \times {ɛ}_{xx} / \cdot a [ t ] \to apnres$$

$$\frac{2 \sqrt{2} qQ Cos [ \frac{π x}{L} ] \sqrt{Vpndc ∈ {N}_{d} {q}_{electron}} {V}_{0} {ν}_{perp}}{h π}$$

The maximum stress (at the center of the beam) is:

$${σ}_{pnmax} = \frac{2 \sqrt{2} qQ \sqrt{Vpndc ∈ {N}_{d} {q}_{electron}} {V}_{0} {ν}_{perp}}{h π} \frac{2 \sqrt{2} qQ \sqrt{Vpndc ∈ {N}_{d} {q}_{electron}} {V}_{0} {ν}_{perp}}{h π}$$

We also note that:

$${ω}_{res} = \sqrt{\frac{{π}^{2} Y}{{L}^{2} ρ}} ;$$

The current that flows to charge the capacitor as the device moves can be used as a detection mechanism. This current could be measured, for example, with a trans impedance amplifier. The current that flows is given by:

$$\frac{\partial }{\partial t} ( CV ) = V \frac{\partial C}{\partial t} + C \frac{\partial V}{\partial t}$$

For the case of a structure vibrating at resonance the term

$$V \frac{\partial C}{\partial t}$$

dominates over the

$$C \frac{\partial V}{\partial t}$$

term. So we have:

$$I = \frac{\partial }{\partial t} ( C V ) = V \frac{\partial C}{\partial t}$$

The capacitance of an area A_{pnc} of the pn junction is given by:

$${C}_{pnt} = \frac{∈ \times Apnc}{wdep} / . \{ Vpnac \to 0 , {N}_{d} \to {N}_{pndt} \}$$

$$\frac{Apnc ∈}{\sqrt{2} \sqrt{\frac{Vpndc ∈}{{N}_{pndt} {q}_{electron}}}}$$

In the above both A_{pnc} and N_{pndt} are understood to be functions of time. N_{pndt} is given by:

$${N}_{pndt} = \frac{{N}_{d}}{( 1 + {ɛ}_{xx} ) \times ( 1 + {ɛ}_{yy} ) \times ( 1 + {ɛ}_{zz} )} ;$$

Since ε_{Xx}, ε_{yy}, ε_{zz} [symbol] 1 we can expand this as:

$${N}_{pndt} = {N}_{d} / ( 1 + {ɛ}_{xx} + {ɛ}_{yy} + {ɛ}_{zz} )$$

$$\frac{{N}_{d}}{\begin{matrix}1 + \frac{π a [ t ] Cos [ \frac{π x}{L} ]}{L} - \\ \frac{π a [ t ] Cos [ \frac{π x}{L} ] {v}_{para}}{L} - \frac{π a [ t ] Cos [ \frac{π x}{L} ] {v}_{perp}}{L}\end{matrix}}$$

Similarly A_{pnc} is given by:

Apnc=Apnc0×(1+εₓₓ)×(1+ε_{yy});

which can be expanded as:

$$Ac = Apnc 0 \times ( 1 + {ɛ}_{xx} + {ɛ}_{yy} )$$

$$Apnc 0 ( 1 + \frac{π a [ t ] Cos [ \frac{π x}{L} ]}{L} - \frac{π a [ t ] Cos [ \frac{π x}{L} ] {v}_{para}}{L} )$$

We are interested in the rate of change of the capacitance with respect to time, which is given by:

$$FullSimplify [ D [ {C}_{pnt} , t ] ]$$

$$\frac{( \begin{matrix}Apnc 0 π Vpndc {∈}^{2} Cos [ \frac{π x}{L} ] \\ ( \begin{matrix}{L}^{2} ( 1 - {v}_{para} + {v}_{perp} ) + 3 {π}^{2} {a [ t ]}^{2} {Cos [ \frac{π x}{L} ]}^{2} \\ {v}_{para} ( - 1 + {v}_{para} + {v}_{perp} ) + L π a [ t ] Cos [ \frac{π x}{L} ] \\ ( 1 - {v}_{perp} + {v}_{para} ( - 6 + {v}_{para} + {v}_{perp} ) )\end{matrix} ) {a}^{′} [ t ]\end{matrix} )}{( \begin{matrix}2 \sqrt{2} {L}^{3} {N}_{d} {q}_{electron} \\ {( \frac{Vpndc ∈ ( L - π a [ t ] Cos [ \frac{π x}{L} ] ( - 1 + {v}_{para} + {v}_{perp} ) )}{L {N}_{d} {q}_{electron}} )}^{3 / 2}\end{matrix} )}$$

$$\frac{( \begin{matrix}Apnc 0 π Vpndc {∈}^{2} Cos [ \frac{π x}{L} ] \\ ( {L}^{2} ( 1 - {v}_{para} + {v}_{perp} ) ) {a}^{′} [ t ]\end{matrix} )}{( 2 \sqrt{2} {L}^{3} {N}_{d} {{q}_{electron} ( \frac{vpndc ∈ L}{L {N}_{d} {q}_{electron}} )}^{3 / 2} )}$$

$$\frac{Apnc 0 π Vpndc {∈}^{2} Cos [ \frac{π x}{L} ] ( 1 - {v}_{para} + {v}_{perp} ) {a}^{′} [ t ]}{2 \sqrt{2} L {{N}_{d} ( \frac{vpndc ∈}{{N}_{d} {q}_{electron}} )}^{3 / 2} {q}_{electron}}$$

Neglecting the small terms (of order εₓₓ²) once again gives us:

$$Simplify [ \frac{( Apnc 0 π Vpndc {∈}^{2} Cos [ \frac{π x}{L} ] ( {L}^{2} ( 1 - {v}_{para} + {v}_{perp} ) ) {a}^{′} [ t ] )}{( 2 \sqrt{2} {L}^{3} {N}_{d} {{q}_{electron} ( \frac{Vpndc ∈ L}{L {N}_{d} {q}_{electron}} )}^{3 / 2} )} ] - \frac{Apnc 0 π Vpndc ∈ Cos [ \frac{π x}{L} ] ( 1 - {v}_{para} + {v}_{perp} ) {a}^{′} [ t ]}{2 \sqrt{2} L \sqrt{\frac{Vpndc ∈}{{N}_{d} {q}_{electron}}}}$$

The differential of the capacitance per unit area with respect to time is therefore:

$$Diff {C}_{pnta} = \% / Apnc 0 /. {a}^{′} [ t ] \to D [ apnres \times Cos [ {ω}_{res} \times t + \frac{π}{2} ] , t ]$$

$$\frac{1}{hY \sqrt{\frac{Vpndc ∈}{{N}_{d} {q}_{electron}}}} ( \begin{matrix}qQ ∈ \sqrt{\frac{Y}{{L}^{2} ρ}} Cos [ \frac{π x}{L} ] \\ Cos [ π t \sqrt{\frac{Y}{{L}^{2} ρ}} ] \\ \sqrt{Vpndc ∈ {N}_{d} {q}_{electron}} \\ {V}_{0} ( - 1 + {v}_{para} - {v}_{perp} ) {v}_{perp}\end{matrix} )$$

NB The (π/2) phase difference results from the resonator being driven at resonance.

The current that flows across the portion of the pn junction at position x along the resonator is given by:

$$δ i = Diff {C}_{pnta} \times Vpndc \times w * δ x$$

$$General \text{: :} spell \text{:}$$

$$Possible spelling error \text{:} new symbol {name }^{``} {δ}^{″} is similar to existing symbols \{ δ x , δ z \} . More …$$

$$\frac{1}{hY \sqrt{\frac{Vpndc ∈}{{N}_{d} {q}_{electron}}}}$$

$$( \begin{matrix}qQVpndcw δ x ∈ \sqrt{\frac{Y}{{L}^{2} ρ}} Cos [ \frac{π x}{L} ] \\ Cos [ π t \sqrt{\frac{Y}{{L}^{2} ρ}} ] \\ \sqrt{Vpndc ∈ {N}_{d} {q}_{electron}} \\ {V}_{0} ( - 1 + {v}_{para} - {v}_{perp} ) {v}_{perp}\end{matrix} )$$

The total current is therefore:

$$i = Simplify [ {\int }_{- L / 2}^{L / 2} \frac{δ i}{δ x} d x ] - \frac{( \begin{matrix}2 LqQVpndcw ∈ \sqrt{\frac{Y}{{L}^{2} ρ}} \\ Cos [ π t \sqrt{\frac{Y}{{L}^{2} ρ}} ] \\ \sqrt{Vpndc ∈ {N}_{d} {q}_{electron}} \\ {v}_{0} {v}_{perp} ( 1 - {v}_{para} + {v}_{perp} )\end{matrix} )}{( h π Y \sqrt{\frac{Vpndc ∈}{{N}_{d} {q}_{electron}}} )}$$

and motional impedance (i.e. applied voltage over the current that is produced) is given by:

$${R}_{mpn} = \frac{{V}_{0} \times Cos [ {ω}_{res} \times t ] / i - ( h π Y \sqrt{\frac{Vpndc ∈}{{N}_{d} {q}_{electron}}} )}{( \begin{matrix}2 LqQVpndcw ∈ \sqrt{\frac{Y}{{L}^{2} ρ}} \\ \sqrt{Vpndc ∈ {N}_{d} {q}_{electron}} \\ {v}_{perp} ( 1 - {v}_{para} + {v}_{perp} )\end{matrix} )}$$

$${R}_{mpn} = - \frac{h π \sqrt{Y \times ρ}}{2 qQwVpndc ∈ {N}_{d} {q}_{electron} {v}_{perp} ( 1 - {v}_{para} + {v}_{perp} )} - \frac{h π \sqrt{Y ρ}}{2 qQwVpndcw ∈ {N}_{d} {q}_{electron} {v}_{perp} ( 1 - {v}_{para} + {v}_{perp} )}$$

Finally we calculate the magnitude of these calculated parameters given various values for the properties of the structure. In the following calculations SI units are assumed (i.e. m for distances, Ω for resistances, Hz for frequencies, F for capacitances).

$$Numerical Values = \{ \begin{matrix}Y \to 170 \times {10}^{9} , \\ ∈ \to 11.9 \times 8.85 \times {10}^{- 12} , \\ {v}_{perp} \to 0.361 , {v}_{para} \to 0.064 , \\ ρ \to 2329 , {V}_{0} \to 1 , Vpndc \to 8 , \\ L \to 2 \times 180 \times {10}^{- 6} , h \to 3 \times {10}^{- 6} , \\ w \to 10 \times {10}^{- 6} , Q \to 180000 , \\ {q}_{electron} \to 1.60 \times {10}^{- 19} , \\ {N}_{d} \to 2 \times {10}^{17} \times {10}^{6} , q \to 1\end{matrix} \} ;$$

$$Table Form [ \{ \begin{matrix}\{ {}_{}^{``}{{a}_{res}}{}_{}^{″} , apnres /. Numerical Values \} , \\ {\{}^{``} {{σ}_{max}}^{″} , {σ}_{pnmax} /. Numerical Values \} , \\ {\{}^{``} {{f}_{res}}^{′′} , N [ \frac{{ω}_{res}}{2 \times π} ] /. Numerical Values \} , \\ {\{}^{``} {C}_{in} / {A}^{″} , \frac{∈}{wdep /. Vpnac \to 0} /. Numerical Values \} , \\ {\{}^{``} {{C}_{in}}^{″} , \frac{∈ \times L \times w}{wdep /. Vpnac \to 0} /. Numerical Values \} , \\ {\{}^{``} {{W}_{depletion}}^{″} , wdep /. Vpnac \to 0 /. Numerical Values \} , \\ {\{}^{``} {{Z}_{in}}^{″} , \frac{wdep /. Vpnac \to 0}{{ω}_{res} \times ∈ \times L \times w} /. Numerical Values \} , \\ {\{}^{``} One port {{R}_{m}}^{″} , - {R}_{mpn} /. Numerical Values \} , \\ \{ `` \frac{1}{ω {C}_{in} {R}_{m}} ″ , \frac{- 1}{( \begin{matrix}{ω}_{res} \times \\ \frac{∈ \times L \times w}{wdep /. vpnac \to 0} \times {R}_{mpn}\end{matrix} )} /. NumericalValues \} ,\end{matrix} \} ]$$

aᵣₑₛ 6.82531×10⁻⁸
νₘₐₓ 1.01256×10⁸
fᵣₑₛ 1.18661×10⁷
Cᵢₙ/A 0.000458944
Cᵢₙ 1.6522×10⁻¹²
W_{depletion} 2.29472×10⁻⁷
Zᵢₙ 8118.02
One port Rₘ 4.12668×10⁶
1/ωCᵢₙRₘ 0.00196721

1. A semiconductor device having a (substantially non-piezoelectric) capacitive actuator, the actuator comprising a depletion region.

2. A semiconductor device according to claim 1, in which the actuator operates through interaction of an electric field and the depletion region.

3. A semiconductor device according to claim 1, in which the device comprises a resonator.

4. A semiconductor device according to claim 1, in which, in use, the depletion region is reverse-biased.

5. A semiconductor device according to claim 1, in which the depletion region is formed by a p-n junction.

6. A semiconductor device according to claim 5, in which the p-n junction is formed between suitably doped regions of the semiconductor device.

7. A semiconductor device according to claim 6, in which at least a portion of the device is formed from a semiconductor which is n-doped and which comprises a p-doped region, and the n-doped semiconductor and the p-doped region form electrode regions of the capacitive actuator.

8. A semiconductor device according to claim 6, in which at least a portion of the device is formed from a semiconductor which is p-doped and which comprises a n-doped region, and the p-doped semiconductor and the n-doped region form electrode regions of the capacitive actuator.

9. A semiconductor device according to claim 6, in which at least one of the doped regions is formed by a process selected from the group consisting of ion-implantation and diffusion.

10. (canceled)

11. A semiconductor device according to claim 1, in which the depletion region is produced by a metal-semiconductor junction or a Schottky barrier.

12. A semiconductor device according to claim 11, which comprises a metal layer applied to a surface of a semiconductor material of the semiconductor device.

13. A semiconductor device according to claim 1, in which the device comprises a semiconductor material, and the depletion region is formed within the semiconductor material.

14. A semiconductor device according to claim 1, in which the device comprises a semiconductor material, and the semiconductor material comprises at least one electrode of the actuator.

15. A semiconductor device according to claim 1, in which the device comprises a semiconductor material, and the semiconductor material comprises all of the electrode regions of the actuator.

16. A semiconductor device according to claim 1, in which the actuator comprises more than one depletion region.

17. A semiconductor device according to claim 1, in which the semiconductor is silicon.

18. A semiconductor device according to claim 1, in which the actuator additionally functions as a sensor.

19. A semiconductor device according to claim 1, further comprising a capacitive sensor, the sensor comprising a depletion region.

20. An actuator for a substantially non-piezoelectric semiconductor device, comprising a depletion region.

21. An actuator according to claim 20, which is additionally operable as a sensor.

22. A method for fabricating a capacitive actuator for a substantially non-piezoelectric semiconductor device, comprising the steps of:
doping a first region of the semiconductor device to form a first electrode region of the capacitive transducer; and
forming a second electrode region of the capacitive transducer:
such that a depletion region is formable between the electrode regions.

23. A method according to claim 22, in which the second electrode region is formed by a step selected from the group consisting of doping a second region of the semiconductor device, forming a layer on a surface of the semiconductor device, and producing a p-n junction.

24. (canceled)

25. (canceled)

26. A method according to claim 22, in which the depletion region is produced by a metal-semiconductor junction or a Schottky barrier.

27. A method according to claim 22, in which at least one of the electrode regions is formed by a process selected from the group consisting of ion implantation and ion diffusion.

28. (canceled)

29. A method according to claim 22, in which more than one depletion region is formed in the capacitive actuator.

30. A method according to claim 22, in which the actuator additionally functions as a sensor, or comprising the step of fabricating a sensor for the semiconductor device, the sensor comprising a depletion region.

31. A method for operating a micromechanical, substantially non-piezoelectric, semiconductor device, comprising the step of:
applying a drive voltage across a depletion region of the semiconductor device.

32. A method according to claim 31, in which the drive voltage comprises a voltage component for reverse-biasing the depletion region.

33. A method according to claim 31, in which the semiconductor device is a resonant device and the drive voltage comprises an alternating voltage component for driving the resonant device.

34. A method according to claim 31, in which the drive voltage is applied between electrodes of a capacitive transducer in order to apply an electric field to the depletion region.

35. (canceled)

36. (canceled)

37. (canceled)

38. (canceled)
